(19) United States
(12) Patent Application Publication
(10) Pub. No.: US 2009/0188426 A1
(43) Pub. Date: Jul. 30, 2009

(54) Crystal-growing furnace with heating improvement structure

(75) Inventors: Shiow-Jeng Lew, Taipei (TW); Hur-Lon Lin, Taipei (TW)

Correspondence Address: BACON & THOMAS, PLLC, 625 SLATERS LANE, FOURTH FLOOR, ALEXANDRIA, VA, 22314-1176, US

(73) Assignee: Green Energy Technology Inc., Taipei (TW)

(21) Appl. No.: 12/222,078

(22) Filed: Aug. 1, 2008

(30) Foreign Application Priority Data
Jan. 29, 2008 (TW) 097103356

(51) Int. Cl. C30B 35/00

(52) U.S. Cl. 117/206

(57) ABSTRACT

A crystal-growing furnace with a heating improvement structure includes a furnace body, a supporting table, a top heater, and a bottom heater. When the silicon material around the top heater is melted, molten silicon slurry will flow directly into the spacing among particles of the silicon material. This will expedite internal part of the silicon material to absorb energy. As a result, a desirable cycle will be established to expedite melting the whole silicon material in the crucible. The crucible is heated at the bottom thereof by the bottom heater directly so as to enhance efficiency in melting the silicon material in the crucible, and to save energy and time consumed by the crystal-growing furnace. Further, since both of the top and the bottom heaters are symmetrical with one another, the crucible can be heated uniformly. This not only saves energy and makes the heating job convenient, but also saves cost in manufacture.

### BACKGROUND OF THE INVENTION

1. Field of the Invention

The present invention relates to a furnace for growing multiple crystals of silicon, more particularly, to a crystal-growing furnace with a heating improvement structure.

2. Description of Related Art

Referring to FIG. 1, a schematic view illustrating a conventional crystal-growing furnace, a heating room 90 is provided inside the furnace 9 where a table plate 91 and a crucible 92 are arranged inside the heating room 90, wherein the crucible 92 contains molten silicon slurry. Three supporting posts 93 are fixed to a lower body 94 of the crystal-growing furnace 9, and are supportively arranged underneath the table plate 91 and the crucible 92.

As shown in FIG. 1, heaters 95 are arranged around the crucible 92 so as to heat the silicon slurry through radiant heat Nevertheless, the top and the bottom of the crucible 92 cannot be heated and uniformly. Besides, in order to provide the crucible 92 a firm and stable support, the table plate 91 must be made very thick, causing the table plate 91 a greater heat capacity. Therefore, a great deal of heat has to be absorbed by the table plate 91, supported by three supporting posts 93, in order to gradually reach to a predetermined temperature. And during a cooling process for a crystal growth, since cooling for the table plate 91 is difficult. So that a great amount of energy and time are wasteful both in heating and cooling process in the crystal-growing furnace.

Further, since the table plate 91 cannot be cooled easily, the silicon slurry in the crucible 92 cannot be cooled uniformly at the lower and the upper portions of the crucible 92, inner stress will incur, after the silicon slurry has been solidified and turned into crystal ingots, resulting in undesirable quality of products.

### SUMMARY OF THE INVENTION

The present invention is to provide a crystal-growing furnace with a heating improvement structure, comprising a furnace body, a supporting table, a top heater, and a bottom heater. The furnace body includes an upper body and a lower body, wherein the lower body is attached to underneath of the upper body so as to form together an enclosed furnace chamber. The supporting table is arranged inside the enclosed furnace chamber, and includes a table plate and a plurality of supporting posts, wherein the table plate is supported by and fixed to the lower body of the crystal-growing furnace by the supporting posts.

According to the present invention, the top heater is arranged inside the furnace chamber, and is positioned correspondingly above the table plate. The top heater includes a first level heater and at least one second level heater, which are fixed to the upper body in a suspension manner. The first level heater is located higher than the second-level heater, where the periphery of the second-level heater is greater than that of the first level heater, and both the first level heater and the second-level heater are formed together as a pyramid-like shape. The bottom heater is assembled together with the table plate of the supporting table.

The crucible is heated simultaneously at the top and bottom thereof by the top and bottom heaters, respectively, so as to enhance efficiency in melting the silicon material in the crucible. Besides, according to the present invention, the first level heater and the second level heater of the top heater are arrayed and arranged in conformity with the silicon material which is stacked and formed as a pyramid-like shape, such that the first level heater and the second level heater get closer to the silicon material and help the silicon material absorb energy at an initiative stage. When the silicon material around the periphery of the pyramid-like shape is melted, molten silicon slurry will flow directly into the spacing among particles of the silicon material. This will expedite internal part of the silicon material to absorb energy. As a result, a desirable cycle will be established to expedite melting the whole silicon material in the crucible so as to save energy and time consumption.

Further, since both of the top and the bottom heaters are simple in geometric configuration, and since the heaters are symmetrical with one another, the crucible can be heated uniformly. This not only saves energy and makes the heating job convenient, but also saves cost in manufacture.

The crystal-growing furnace comprises a heating room arranged inside the furnace chamber of the furnace body, and is formed inside of the heating room with an inner space which accommodates, at least, the table plate of the supporting table, the top heater, and the bottom heater. Besides, the heating room has a double-layer structure, including an internal insulating layer and an external warm-keeping layer, such that the internal insulating layer serves to prevent heat from leaking out of the heating room, while the external warm-keeping layer can enhance warm-keeping effectiveness so as to achieve the purpose of energy saving.

Further, the heating room includes an upper cover and a lower partition, where the upper cover is covered on the lower partition so as to enclose and form together the inner space. The lower partition of the heating room is fixed to the lower body, and is provided with a plurality of through holes, wherein a plurality of sleeves pass through the plural through holes, respectively, and wherein the plural supporting posts are received in the plural sleeves and fixed to the lower body. The upper cover of the heating room includes an upper partition and a plurality of side partitions, where the plural side partitions are arrayed from one another and around underneath of the upper partition.

According to the present invention, the first level heater of the top heater includes a surrounding resistor and two graphite electrodes, where the two graphite electrodes are connected, respectively, with the surrounding resistor so as to provide electrical power to the first level heater for heating purpose. Further, there may be provided with a third level heater having a periphery greater than that of the second level heater; or even be provided with a fourth or fifth level heater having a greater periphery so as to form together a pyramid-like shape. The heaters may be connected in series as a polygon or in an annular shape so as to conform to various shapes of the crucible.

The second level heater of the top heater includes a surrounding resistor and two graphite electrodes, where the two graphite electrodes are connected, respectively, with the surrounding resistor so as to provide electrical power to the second level heater for heating purpose. The bottom heater includes a plurality of bending resistor strips disposed, respectively, underneath the table plate of the supporting table. Each of the supporting posts includes a graphite electrode post for supporting underneath one of the resistor strips and for electrically connecting therewith. There are a plurality of insulating sheets interposed between the table plate of the supporting table and the plural bending resistor strips. Further, each of the supporting posts has an adjusting nut. The graphite electrode posts are each provided, at its top, with an external thread so that the adjusting nuts can be engaged with the external threads and thus support against the bending resistor strips. This will not only enlarge electrical contacting area, but also enhance stability in supporting the table plate. The adjusting nut is made of graphite.

Other objects, advantages, and novel features of the present invention will become more apparent from the following detailed description when taken in conjunction with the accompanying drawings.

### BRIEF DESCRIPTION OF THE DRAWINGS

FIG. 1 is a schematic view illustrating a conventional crystal-growing furnace;

FIG. 2 is a cross-sectional view illustrating a crystal-growing furnace according to the present invention;

FIG. 3 is a schematic view illustrating a top heater according to the present invention;

FIG. 4 is a schematic view illustrating a bottom heater according to the present invention; and

FIG. 5 is a perspective view illustrating the bottom heater according to the present invention.

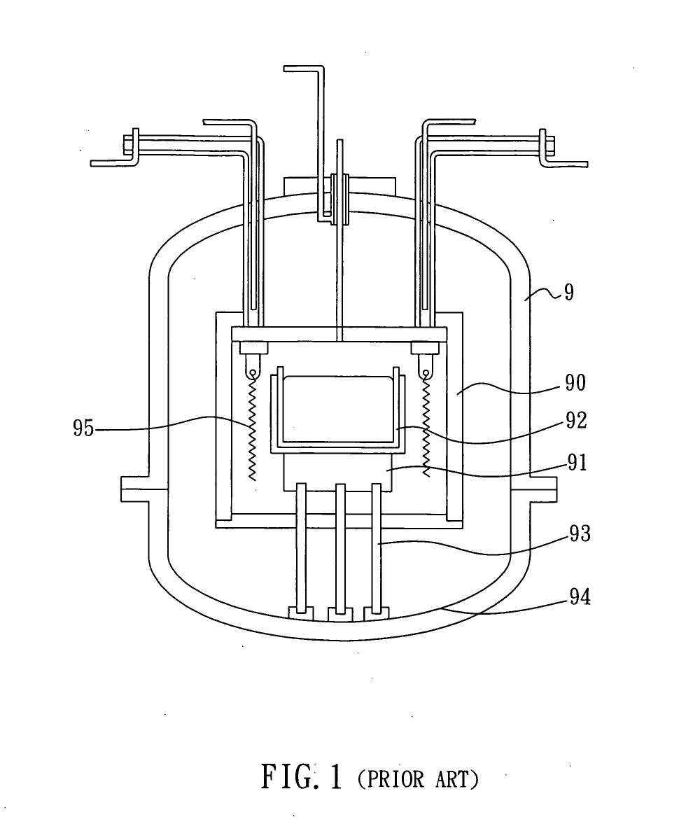

### DETAILED DESCRIPTION OF THE PREFERRED EMBODIMENTS

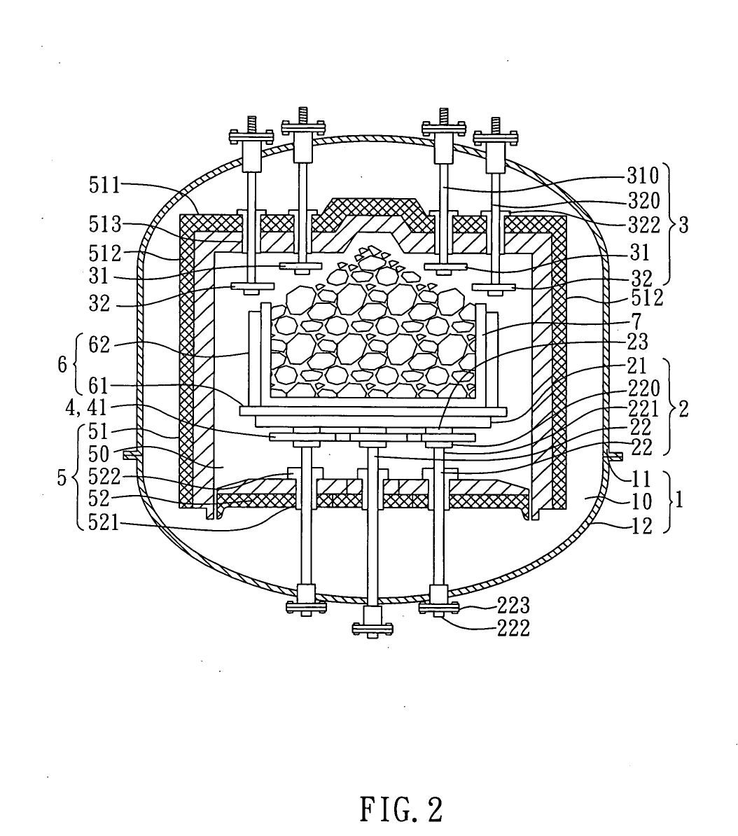

Referring to FIG. 2, a cross-sectional view illustrating a crystal-growing furnace, the crystal-growing furnace comprises a furnace body 1, a supporting table 2, a top heater 3, and a bottom heater 4.

The furnace body 1 includes an upper body 11 and a lower body 12, wherein the lower body 12 is attached to underneath of the upper body 11 so as to form together an enclosed furnace chamber 10. The supporting table 2 includes a table plate 21 and eight supporting posts 22, wherein the table plate 21 is supported by and fixed to the lower body 12 of the crystal-growing furnace by the supporting posts 22.

As shown in FIG. 2, a heating room 5 is arranged inside the furnace chamber 10 of the furnace body 1, and includes an upper cover 51 and a lower partition 52. The upper cover 51 is fixed to inside of the upper body 11, and the lower partition 52 fixed to inside of the lower body 12, such that the upper cover 51 is covered on the lower partition 52 so as to enclose and form together an inner space 50. The inner space 50 accommodates, at least, the table plate 21 of the supporting table 2, the top heater 3, and the bottom heater 4.

Further, the lower partition 52 of the heating room 5 is provided with eight through holes 521, wherein eight sleeves 522 pass through the eight through holes 521, respectively, and wherein the eight supporting posts 22 are received in the eight sleeves 522 and fixed to the lower body 12. The upper cover 51 of the heating room 5 includes an upper partition 511 and four side partitions 512, where the side partitions 512 are arrayed from one another and around underneath of the upper partition 511. The upper partition 511 is provided with four through holes 513, wherein four sleeves 322 pass through the four through holes 513, respectively, and wherein four graphite electrodes 310,320 are received in the four sleeves 322 and fixed to inside of the upper body 11.

The heating room 5 has a double-layer structure, including an internal insulating layer (such as made of graphite insulating material) and an external warm-keeping layer (such as made of alumina fiber), such that the internal insulating layer serves to prevent heat leaking out of the heating room 5, while the external warm-keeping layer can enhance warm-keeping effectiveness so as to achieve the purpose of energy saving.

As shown in FIG. 2, a loading frame 6 is disposed on the table plate 21 of the supporting table 2, and includes a lower plate 61 and four side plates 62, where the side plates 62 surround and stand on the lower plate 61 which envelop and form together an inner space for receiving therein a crucible 7.

The top heater 3 is arranged inside the heating room 5 of the furnace chamber 10, and is positioned correspondingly above the table plate 21. The top heater 3 has a heating structure with at least two levels, namely including a first level heater 31 and a second level heater 32 which are fixed to the upper body 11 in a suspension manner. The first level heater 31 is located higher than the second level heater 32, where both the first level heater 31 and the second level heater 32 are shaped as a hollow frame, and where the periphery of the second level heater 32 is greater than that of the first level heater 31, both formed together as a pyramid-like shape. The bottom heater 4 is assembled together with the table plate 21 of the supporting table 2.

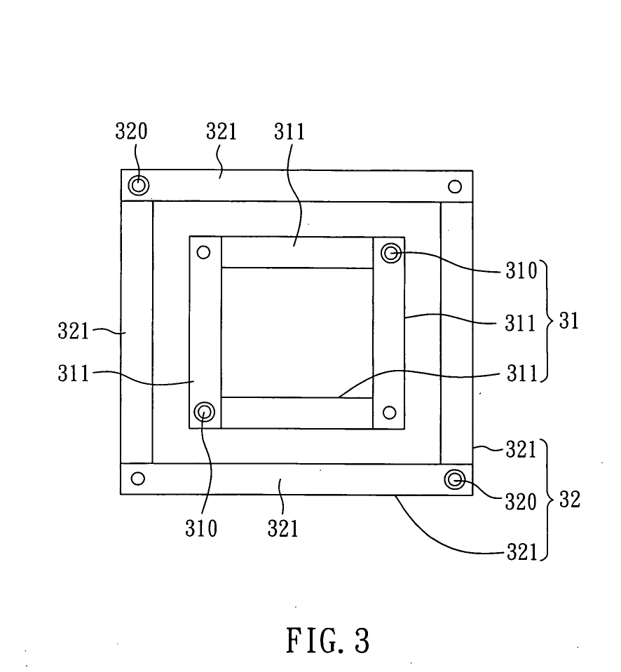

Now referring to FIG. 3, a schematic view illustrating the top heater according to the present invention, the first level heater 31 of the top heater 3 includes a surrounding resistor and two graphite electrodes 310, where the surrounding resistor is formed with four resistor plates 311 which are connected in series as a square-like shape so as to conform with the crucible 7 which is square in shape. The two graphite electrodes 310 are connected, respectively, with the surrounding resistor so as to provide electrical power to the first level heater 31 for heating purpose. Further, the second level heater 32 of the top heater 3 includes a surrounding resistor and two graphite electrodes 320, where the surrounding resistor is formed with four longer resistor plates 321 which are connected in series as a square-like shape so as to conform with the shape of the crucible 7. The two graphite electrodes 320 are connected, respectively, with the surrounding resistor so as to provide electrical power to the second level heater 32 for heating purpose.

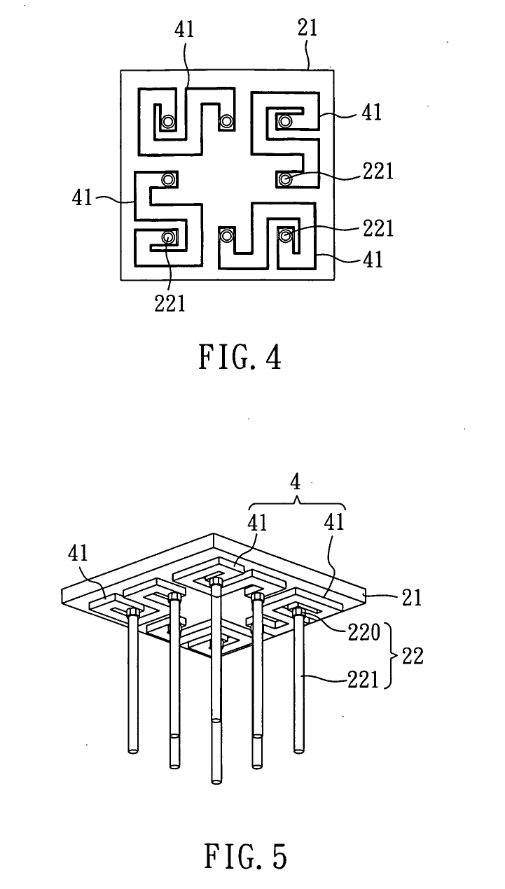

Further, referring to FIG. 4, a schematic view illustrating a bottom heater according to the present invention, and also to FIG. 2, the bottom heater 4 includes four bending resistor strips 41 disposed, respectively, underneath the table plate 21 of the supporting table 2. The supporting posts 22 each includes a graphite electrode post 221 for supporting underneath the resistor strip 41 and for electrically connecting therewith, such that electrical power can be provided through the graphite electrode posts 221 for heating the resistor strips 41. As shown in FIG. 2, a plurality of insulating sheets 23 are interposed between the table plate 21 of the supporting table 2 and the four bending resistor strips 41.

Referring to FIG. 2, the supporting posts 22 are fixed to the wall of the lower body 11 such that anchoring means 223 are first welded to the wall of the lower body 11, and then the anchoring means 223, the graphite electrode posts 221 and metal posts 222 are screwed together and are electrically connected therewith.

Further, referring to FIG. 5, a perspective view illustrating the bottom heater according to the present invention, the supporting posts 22 each has an adjusting nut 220 which is made of graphite. The graphite electrode posts 221 are each provided, at its top, with an external thread so that the adjusting nuts 220 can be engaged with the external threads and thus support against the bending resistor strips 41. This will not only enlarge electrical contacting area, but also enhance stability in supporting the table plate 21.

As mentioned above, the crucible 7 is heated simultaneously at the top and bottom thereof by the top and bottom heaters 3,4, respectively, so as to enhance efficiency in melting the silicon material in the crucible 7. Besides, according to the present invention, the first level heater 31 and the second level heater 32 are arrayed and arranged in conformity with the silicon material which is stacked and formed as a pyramid-like shape, so that the first level heater 31 and the second level heater 32 get closer to the silicon material and help the silicon material absorb energy at an initiative stage. When the silicon material around the periphery of the pyramid-like shape is melted, molten silicon slurry will flow directly into the spacing among particles of the silicon material. This will expedite internal part of the silicon material to absorb energy. As a result, a desirable cycle will be established to expedite melting the whole silicon material in the crucible 7 so as to save energy and time consumption.

As shown in FIGS. 3 and 4, since both of the top and the bottom heaters 3,4 are simple in geometric configuration, and since the heaters are symmetrical with one another, the crucible 7 can be heated uniformly. This not only saves energy and makes the heating job convenient, but also saves cost in manufacture.

Although the present invention has been explained in relation to its preferred embodiments, it is to be understood that many other possible modifications and variations can be made without departing from the scope of the invention as hereinafter claimed.

What is claimed is:

1. A crystal-growing furnace with a heating improvement structure, comprising:
a furnace body, including an upper body and a lower body, wherein the lower body is attached to underneath of the upper body so as to form together an enclosed furnace chamber; and
a supporting table, being arranged inside the enclosed furnace chamber, and including a table plate and a plurality of supporting posts, wherein the table plate is supported by and fixed to the lower body of the crystal-growing furnace by the supporting posts;
characterized in that:
a top heater is arranged inside the furnace chamber and positioned correspondingly above the table plate, and includes a first level heater and at least one second level heater, which are fixed to the upper body in a suspension manner, wherein the first level heater is located higher than the second-level heater, and the periphery of the second-level heater is greater than that of the first level heater; and
a bottom heater is assembled together with the table plate of the supporting table.

2. The crystal-growing furnace as claimed in claim 1, further comprising a heating room arranged inside the furnace chamber of the furnace body, and being formed inside of the heating room with an inner space which accommodates, at least, the table plate of the supporting table, the top heater, and the bottom heater.

3. The crystal-growing furnace supporting table as claimed in claim 2, wherein the heating room has a double-layer structure, including an internal insulating layer and an external warm-keeping layer

4. The crystal-growing furnace as claimed in claim 2, wherein the heating room includes an upper cover and a lower partition, and the upper cover is covered on the lower partition so as to enclose and form together the inner space.

5. The crystal-growing furnace as claimed in claim 4, further comprising a plurality of sleeves, wherein the lower partition of the heating room is provided with a plurality of through holes, and the plural sleeves pass through the plural through holes, respectively, and the plural supporting posts are received in the plural sleeves and are fixed to the lower body.

6. The crystal-growing furnace as claimed in claim 4, wherein the upper cover of the heating room includes an upper partition and a plurality of side partitions, and the plural side partitions are arrayed from one another and around underneath of the upper partition.

7. The crystal-growing furnace as claimed in claim 1, wherein the first level heater of the top heater includes a surrounding resistor and two graphite electrodes, and the two graphite electrodes are electrically connected, respectively, with the surrounding resistor.

8. The crystal-growing furnace as claimed in claim 1, wherein the at least one second level heater of the top heater includes a surrounding resistor and two graphite electrodes, and the two graphite electrodes are electrically connected, respectively, with the surrounding resistor.

9. The crystal-growing furnace as claimed in claim 1, wherein the bottom heater includes a plurality of bending resistor strips disposed, respectively, underneath the table plate of the supporting table, and each of the supporting posts includes a graphite electrode post for supporting underneath one of the resistor strips and for electrically connecting therewith.

10. The crystal-growing furnace as claimed in claim 9, further comprising a plurality of insulating sheets interposed between the table plate of the supporting table and the plural bending resistor strips.

11. The crystal-growing furnace as claimed in claim 9, wherein each of the supporting posts has an adjusting nut, and the graphite electrode posts are each provided, at its top, with an external thread so that the adjusting nuts can be engaged with the external threads and thus support against the bending resistor strips.

12. The crystal-growing furnace as claimed in claim 11, wherein the adjusting nut is made of graphite.
